(19) United States
(12) Patent Application Publication
(10) Pub. No.: US 2025/0043149 A1
(43) Pub. Date: Feb. 6, 2025

(54) SLURRY COMPOSITION FOR CHEMICAL MECHANICAL POLISHING AND CHEMICAL MECHANICAL POLISHING APPARATUS

(71) Applicant: Samsung Electronics Co., Ltd., Suwon-si (KR)

(72) Inventors: DONGHOON KWON, Suwon-si (KR); BOUN YOON, Suwon-si (KR)

(21) Appl. No.: 18/430,808

(22) Filed: Feb. 2, 2024

(30) Foreign Application Priority Data
Aug. 3, 2023 (KR) 10-2023-0101676

(51) Int. Cl. C09G 1/02; B24B 57/02; C09K 3/14

(52) U.S. Cl. CPC C09G 1/02; B24B 57/02; C09K 3/1436

(57) ABSTRACT

Provided are a slurry composition for chemical mechanical polishing including: an abrasive including a polishing particle and a coating layer surrounding the polishing particle; and a photoinitiator, wherein the polishing particle includes a metal oxide, and wherein the coating layer includes a photoreactive monomer or oligomer, and a chemical mechanical polishing apparatus.

### CROSS-REFERENCE TO RELATED APPLICATION

This application claims priority to and the benefit of Korean Patent Application No. 10-2023-0101676 filed on Aug. 3, 2023 in the Korean Intellectual Property Office, the entire contents of which are herein incorporated by reference.

### BACKGROUND

### 1. Field

An aspect of the present disclosure relates to a slurry composition for chemical mechanical polishing and a chemical mechanical polishing apparatus using the same.

### 2. Description of the Related Art

A chemical mechanical polishing (CMP) apparatus is used in a polishing process of planarizing a surface of a wafer. In general, a semiconductor device is manufactured by selectively or repeatedly performing processes such as photolithography, etching, diffusion, chemical vapor deposition, ion implantation, and metal deposition on a wafer. In the process, the wafer undergoes a chemical mechanical polishing (CMP) process as a planarization process to facilitate formation of a circuit pattern on the surface of the wafer.

In a CMP process, slurry is uniformly distributed on a surface of a polishing pad rotating at high speed, and the surface of the wafer for which planarization is placed near the surface of the polishing pad, thereby processing a target surface of the wafer through a chemical action by the slurry and a physical action by high-speed rotation.

In such a CMP process, research is being conducted to optimize process control parameters such as pressure, speed, and temperature. However, with the increasing difficulty of semiconductor product technology development, control of such conventional process control parameters is insufficient to address the increasing process complexities.

### SUMMARY

The present disclosure attempts to provide a slurry composition for chemical mechanical polishing excellent in polishing performance by improving an ability to remove steps on a wafer.

The present disclosure also attempts to provide a chemical mechanical polishing apparatus using the slurry composition for chemical mechanical polishing.

An embodiment provides a slurry composition for chemical mechanical polishing including: an abrasive including a polishing particle and a coating layer surrounding the polishing particle; and a photoinitiator, wherein the polishing particle includes a metal oxide, and wherein the coating layer includes a photoreactive monomer or oligomer, and a chemical mechanical polishing apparatus using the slurry composition.

An embodiment provides a chemical mechanical polishing apparatus including: a polishing platen including a light irradiation member; a polishing pad located on the polishing platen; and a slurry supplier configured to supply a slurry composition for chemical mechanical polishing to the polishing pad.

An embodiment provides a chemical mechanical polishing apparatus including: a polishing platen including a light irradiation member; a transparent polishing pad located on the polishing platen; and a slurry supplier configured to supply a slurry composition for chemical mechanical polishing to the polishing pad.

The slurry composition for chemical mechanical polishing according to an embodiment has a composition that undergoes polymerization when irradiated with light. Therefore, when the slurry composition is used for a chemical mechanical polishing apparatus, the ability to remove steps on a wafer can be enhanced through agglomeration of abrasives based on the polymerization. Accordingly, excellent polishing performance can be secured.

### BRIEF DESCRIPTION OF THE DRAWINGS

FIG. 1 is a cross-sectional view of a chemical mechanical polishing apparatus according to an embodiment.

FIG. 2 is a schematic diagram showing an abrasive according to an embodiment.

FIG. 3 is a schematic diagram showing agglomeration of abrasives through polymerization when irradiated with light in a slurry composition for chemical mechanical polishing according to an embodiment.

FIG. 4 is a schematic diagram showing an action of the abrasive according to an embodiment when irradiated with light during a wafer polishing process.

FIG. 5 is a cross-sectional view of a chemical mechanical polishing apparatus according to an embodiment.

FIG. 6A to FIG. 6D are cross-sectional views of the polishing platen showing examples of the polishing platen in the chemical mechanical polishing apparatus of FIG. 5.

### DETAILED DESCRIPTION

In the following detailed description, only certain embodiments have been shown and described, simply by way of illustration. The present invention can be variously implemented and is not limited to the following embodiments.

The drawings and description are to be regarded as illustrative in nature and not restrictive. Like reference numerals designate like elements throughout the specification.

The size and thickness of each configuration shown in the drawings are arbitrarily shown for understanding and ease of description, but the present invention is not limited thereto. In the drawings, the thickness of layers, films, panels, regions, etc., are exaggerated for clarity. In the drawings, for understanding and ease of description, the thickness of some layers and areas is exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

Unless explicitly described to the contrary, the word “comprise”, and variations such as “comprises” or “comprising”, will be understood to imply the inclusion of stated elements but is not the exclusion of any other elements.

In the specification, when it is referred to as “on a plane”, it means when a target part is viewed from above, and when it is referred to as “on a cross-section”, it means when the cross-section obtained by cutting a target part vertically is viewed from the side.

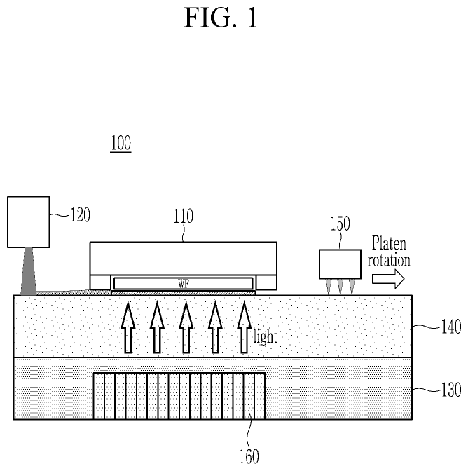

FIG. 1 is a cross-sectional view of a chemical mechanical polishing apparatus according to an embodiment.

Referring to FIG. 1, a chemical mechanical polishing apparatus 100 is an apparatus for polishing a wafer WF, and includes a head unit 110, a slurry supplier 120, a polishing platen 130, a polishing pad 140, and a conditioner 150. The chemical mechanical polishing apparatus 100 performs mechanical polishing while the wafer (WF) mounted on a bottom of the head unit 110 is in contact with the polishing pad 140, and performs chemical polishing through a chemical reaction by a slurry composition supplied from the slurry supplier 120. The term “contact,” as used herein, refers to a direct connection (i.e., physical touching) unless the context indicates otherwise.

The slurry supplier 120 is a member that supplies a slurry composition as described below to the polishing pad 140. The polishing platen 130 includes a light irradiation member 160 for irradiation of light to perform a light reaction with the slurry composition supplied from the slurry supplier 120.

A detailed description of each member of the chemical mechanical polishing apparatus 100 will be described below, and the slurry composition to be supplied to the slurry supplier 120 will be described below.

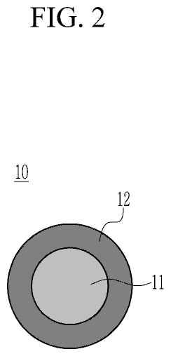

A slurry composition for chemical mechanical polishing according to an embodiment includes an abrasive and a photoinitiator. The abrasive and the photoinitiator are described with reference to FIGS. 2 to 4.

### Abrasive

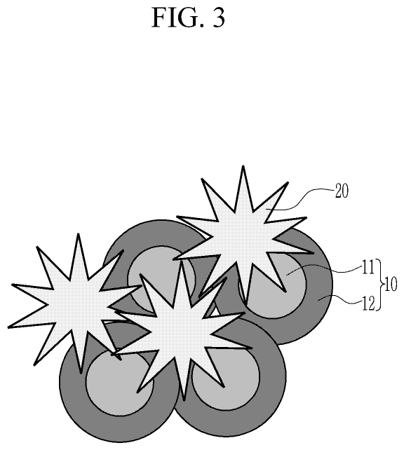

FIG. 2 is a schematic diagram showing an abrasive according to an embodiment, and FIG. 3 is a schematic diagram showing agglomeration of abrasives through polymerization when irradiated with light in a slurry composition for chemical mechanical polishing according to an embodiment.

Referring to FIGS. 2 and 3, the abrasive 10 includes a polishing particle 11 and a coating layer 12 surrounding the polishing particle 11, and has a core-shell structure. For example, the outer surface of the polishing particle 11 is coated with the coating layer 12 to form the core-shell structure. In an embodiment, the entire outer surface of the polishing particle 11 is coated with the coating layer 12. The polishing particle 11 includes a metal oxide, and the coating layer 12 includes a photoreactive monomer or oligomer.

The slurry composition for chemical mechanical polishing according to an embodiment includes the abrasive 10 and a photoinitiator 20 as described below, and causes polymerization when irradiated with light, thereby enhancing an ability to remove steps on the wafer through agglomeration of the abrasives 10 by such polymerization. Accordingly, excellent polishing performance can be secured.

Specifically, the polishing particle 11 may be made of a metal oxide including SiO₂, Al₂O₃, CeO₂, ZrO₂, TiO₂, MnO₂, Mn₂O₃ or a combination thereof. In an embodiment, two or more example polishing particles may be used in a mixture thereof.

The coating layer 12 may be made of a photoreactive monomer or oligomer that can cause polymerization through a driving force transmitted by the photoinitiator 20 when irradiated with light by the light irradiation member 160. For example, the material of the coating layer 12 is polymerized by radicals or cations generated as a result of decomposition of the photoinitiator 20 when irradiated with light, and the abrasives 10 may agglomerate with each other via the polymerization. The agglomerated abrasives 10 can enhance the ability to remove steps on the wafer, thereby ensuring excellent polishing performance.

Specifically, the photoreactive monomer or oligomer may include a radically polymerizable compound, a cationically polymerizable compound, or a combination thereof. In an embodiment, two or more example photoreactive monomers or oligomers may be used in a mixture thereof.

The radically polymerizable compound is a compound that is polymerized by radicals generated as a result of decomposition of a photoinitiator, and may include, but is not limited to, a (meth) acrylate-based compound, a thiol-based compound, an alkene-based compound, an alkyne-based compound, or a combination thereof. In an embodiment, two or more example radically polymerizable compounds may be used in a mixture thereof.

The (meth) acrylate-based compound may be a compound having a (meth) acrylate group in a molecular structure. Non-limiting examples of the (meth) acrylate-based compound may include polyethylene glycol diacylate (PEGDA), urethane dimethacrylate (UDMA), triethylenglycol dimethacrylate (TEGDMA), bisphenol A glycidyl methacrylate (Bis-GMA), trimethylolpropane triacrylate (TTA), or bisphenol A ethoxylate diacrylate (Bis-EDA). One or more of these may be used as the (meth) acrylate-based compound. In an embodiment, two or more of the example (meth) acrylate-based compounds may be used in a mixture thereof.

The thiol-based compound may be a compound having a thiol group in a molecular structure. Non-limiting examples of the thiol-based compound may include trimethylolpropane tris(3-mercaptopropionate) (TMPMP), pentaerythritol tetra(3-mercaptopropionate) (PETMP), tris [2-(3-mercaptopropionyloxy)ethyl] isocyanurate (TMI), or pentaerythritol tetrakis(3-mercaptopropionate) (PE-1). One or more of these may be used as the thiol-based compound. In an embodiment, two or more of the example thiol-based compounds may be used in a mixture thereof.

The alkene-based compound may be a compound having an alkene structure in a molecular structure. Non-limiting examples of the alkene-based compound may include triallyl-1,3,5-triazine-2,4,6 (1H,3H,5H)-trione (TTT).

The alkyne-based compound may be a compound having an alkyne structure in a molecular structure. Non-limiting examples of the alkyne-based compounds may include 1,4-butandiol dipent-4-yn-2-yl carbonate (4MPC), 2,2-bis [4-(2-hydroxy) ethoxyphenyl] propane dibut-3-yn-1-yl carbonate (BABC), or tricyclo[5.2.1.0 (2,6)] decane-4,8-dimethanol dibut-3-yn-1-yl carbonate (TCBC). One or more of these may be used as alkyne-based compound. In an embodiment, two or more of the example alkyne-based compounds may be used in a mixture thereof.

The cationically polymerizable compound is a compound that is polymerized by cations generated from decomposition of a photoinitiator, and may include, but is not limited to, an epoxy-based compound, a vinyl ether-based compound, an oxetane-based compound, or a combination thereof as a monomer or oligomer.

The epoxy-based compound may be a compound having an epoxy group in a molecular structure. Non-limiting examples of the epoxy-based compound may include 3,4-epoxycyclohexylmethyl-3,4-epoxycyclohexanecarboxylate (EPOX), or bisphenol A diglycidylether (DGEBA). One or more of these may be used as the epoxy-based compound. In an embodiment, two or more of the example epoxy-based compounds may be used in a mixture thereof.

The vinyl ether-based compound may be a compound having a vinyl ether group in a molecular structure. Non-limiting examples of the vinyl ether-based compound may include 1,4-cyclohexane dimethanol divinylether (CDVE).

The oxetane-based compound may be a compound having an oxetane structure in a molecular structure. Non-limiting examples of the oxetane-based compound may include disubstituted oxetane (DSO).

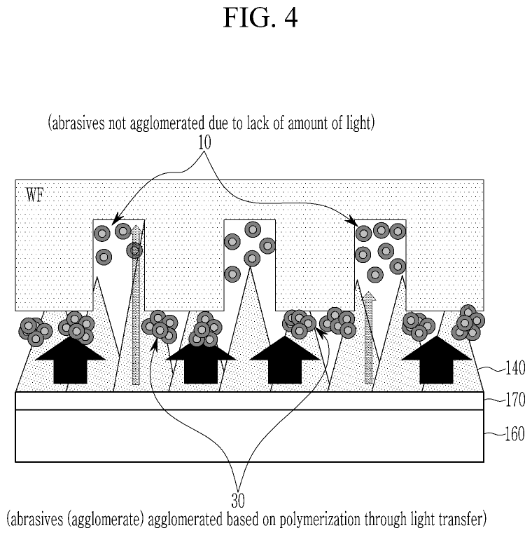

FIG. 4 is a schematic diagram showing an action of the abrasive according to an embodiment when irradiated with light during a wafer polishing process.

Referring to FIG. 4, when exposed to light, the abrasive 10 undergoes polymerization through the previously mentioned photoreactive monomer or oligomer, facilitated by the photoinitiator 20. As a result, the abrasives 10 agglomerate through polymerization to form an agglomerate 30. The agglomerate 30 can enhance the ability to remove steps on the wafer.

The abrasive 10 may form the coating layer 12 by coating a surface of the polishing particle 11 with the photoreactive monomer or oligomer. The abrasive 10 may be manufactured by adding the photoreactive monomer or oligomer when synthesizing the polishing particle 11. Specifically, when the functional group in the photoreactive monomer or oligomer has an opposite charge to the surface of the polishing particle 11, the coating may be made through mixing of the polishing particle 11 and the photoreactive monomer or oligomer.

A diameter of the polishing particle 11 may be 10 nm to 300 nm, for example, 20 nm to 280 nm. When the diameter of the polishing particle 11 is within the above range, agglomeration of the abrasives based on polymerization occurs smoothly when irradiated with light, leading to improvement in ability to remove steps on the wafer.

A thickness of the coating layer 12 may be 0.001 nm to 10 nm, for example, 0.01 nm to 8 nm. When the thickness of the coating layer 12 is within the above range, a polymerization reaction occurs smoothly upon light irradiation, so that agglomeration of abrasives based on the polymerization is facilitated, leading to improvement in ability to remove steps on the wafer.

The abrasive 10 may be included in an amount of 0.1% by weight to 10% by weight, for example, 0.5% by weight to 8% by weight, with respect to a total amount of the slurry composition for chemical mechanical polishing. For example, the “% by weight” of the abrasive 10 may be obtained by dividing a mass (e.g., gram) of the abrasive 10 included in the slurry composition by a mass (e.g., gram) of the slurry composition. When the abrasive 10 is included within the above range, the ability to remove steps on the wafer is improved, thereby ensuring excellent polishing performance.

### Photoinitiator

The photoinitiator 20 may be a material that can generate a polymerization driving force by light energy when irradiated with light. That is, the photoinitiator is decomposed upon light irradiation to generate radicals or cations, and the generated radicals or cations polymerize the photoreactive monomer or oligomer of the coating layer 12 to induce agglomeration of the abrasives 10, thereby enhancing the ability to remove steps on the wafer.

In an embodiment, the photoinitiator 20 may include a radical initiator, a cationic initiator, or a combination thereof. In an embodiment, two or more example photoinitiators may be used in a mixture thereof.

The radical initiator is a substance that generates radicals when irradiated with light, and may include, but is not limited to, an azo compound, a peroxide compound, a halogen compound, or a combination thereof. In an embodiment, two or more example radical initiators may be used in a mixture thereof.

The azo compound may be a compound having an azo group. The azo compound may include, but is not limited to, 2,2′-azobis(isobutyronitrile), 2,2′-azobis [2-(2-imidazolin-2-yl) propane] dihydrochloride, 2,2′-azobis{2-[1-(2-hydroxyethyl)-2-imidazolin-2-yl]propane} dihydrochloride, 2,2′-azobis {2-methyl-N-[1,1-bis(hydroxymethyl)-2-hydroxyethyl] propionamide, 2,2′-azobis [2-methyl-N-(2-hydroxyethyl) propionamide], 2,2′-azobis {2-methyl-N-[2-(1-hydroxybutyl)] propionamide}, 2,2′-azobis(2-methylpropionamide)dihydrochloride, or 2,2′-azobis [N-(2-carboxyethyl)-2-methylpropionamidine] tetrahydrate. In an embodiment, one or more of these may be used as the azo compound. In an embodiment, two or more of the example azo compounds may be used in a mixture thereof.

The peroxide compound may be a compound having a peroxide group. Non-limiting examples of the peroxide compound may include benzoyl peroxide, di-t-butyl hydroperoxide, or acetyl peroxide. One or more of these may be used as the peroxide compound. In an embodiment, two or more of the example peroxide compounds may be used in a mixture thereof.

The halogen compound may be a compound having a halide group or a halogen element. Non-limiting examples of the halogen compound may include N-bromo succinimide, F₂, Cl₂, Br₂, or I₂. One or more of these may be used as the halogen compound. In an embodiment, two or more of the example halogen compounds may be used in a mixture thereof.

The cationic initiator is a material that generates cations when irradiated with light, and may include, but is not limited to, a diazosulfone compound, a sulfonium salt, an iodonium salt, a sulfonate compound, or a combination thereof. In an embodiment, two or more example cationic initiators may be used in a mixture thereof.

The diazosulfone compound may be a compound having an azo group and a sulfonyl group. Non-limiting examples of the diazosulfone compounds may include bis(cyclohexylsulfonyl)diazomethane, bis(t-butylsulfonyl) diazomethane, or bis(p-toluenesulfonyl)diazomethane. One or more of these may be used as the diazosulfone compound. In an embodiment, two or more example diazosulfone compounds may be used in a mixture thereof.

Non-limiting examples of the sulfonium salt may include diphenyl-4-methylphenylsulfonium trifluoromethanesulfonate, diphenyl-4-methylphenylsulfonium perfluorobutanesulfonate, diphenyl-4-methoxylphenylsulfonium trifluoromethanesulfonate, or triaryl sulfonium hexafluorophosphate. One or more of these may be used as the sulfonium salt. In an embodiment, two or more example sulfonium salts may be used in a mixture thereof.

Non-limiting examples of the iodonium salt may include diphenyl iodonium trifluoromethanesulfonate, diphenyl iodonium camphormethylsulfonate, or iodonium ylidene bis(4,1-phenyleneoxy-4,1-phenylene)bis[disphenylsulfonium] tri(hexafluorophosphate)]. One or more of these may be used as the iodonium salt. In an embodiment, two or more iodonium salts may be used in a mixture thereof.

Non-limiting examples of the sulfonate compound may include N-hydroxy-5-norbornene-2,3-dicarboximide trifluoromethanesulfonate, or N-hydroxy-5-norbornene-2,3-dicarboximide perfluoro-1-butanesulfonate. One or more of these may be used as the sulfonate compound. In an embodiment, two or more sulfonate compounds may be used in a mixture thereof.

The photoinitiator 20 may be included in an amount of 0.01% by weight to 1% by weight, for example, 0.05% by weight to 0.5% by weight, with respect to the total amount of the slurry composition for chemical mechanical polishing. When the photoinitiator 20 is included within the above range, the ability to remove steps on the wafer is improved, thereby ensuring excellent polishing performance.

For example, the slurry composition for chemical mechanical polishing according to an embodiment may include an abrasive 10 in which a polishing particle 11 is surrounded by a coating layer 12 including a radically polymerizable compound, and the photoinitiator 20 as a radical initiator. In an embodiment, the slurry composition for chemical mechanical polishing according to an embodiment may include, for example, an abrasive 10 in which a polishing particle 11 is surrounded by a coating layer 12 including a cationically polymerizable compound, and the photoinitiator 20 as a cationic initiator.

As described above, the slurry composition for chemical mechanical polishing according to an embodiment may further include one or more of a pH control agent, a polishing accelerator, an oxidizing agent, a surfactant, a polishing inhibitor, a leveling agent, a corrosion inhibitor, an amine compound, a catalyst, a chelator, a carrier, and the like.

### pH Controlling Agent

The slurry composition for chemical mechanical polishing may further include a pH control agent for regulating pH of the composition. The slurry composition for chemical mechanical polishing may have a pH of 1 to 9, for example, 2 to 7.

The pH control agent may include, but is not limited to, an acid solution such as sulfuric acid, phosphoric acid, hydrochloric acid, nitric acid, carboxylic acid, maleic acid, malonic acid, citric acid, oxalic acid, and tartaric acid; an alkaline solution such as calcium hydroxide, potassium hydroxide, ammonium hydroxide, sodium hydroxide, magnesium hydroxide, triethylamine, tetramethylammonium hydroxide, and ammonia; or a combination thereof. In an embodiment, the pH control agent may include a mixture of the acid solution and the alkaline solution.

The pH control agent may be included in the slurry composition for chemical mechanical polishing in an amount that allows the slurry composition to have a desired pH.

### Polishing Accelerator

The polishing accelerator used in chemical mechanical polishing may include an anionic-based low-molecular weight material, an anionic-based high-molecular weight material, a hydroxyl acid, or an amino acid.

The anionic-based low-molecular weight material may include, for example, at least one of citric acid, polyacrylic acid, polymethacrylic acid, a copolymer acid, and a salt thereof. The hydroxyl acid may include, for example, at least one of hydroxylbenzoic acid, ascorbic acid, and a salt thereof. The amino acid may include, for example, picolinic acid, serine, proline, arginine, asparagine, aspartic acid, cysteine, glutamine, glutamic acid, glycine, histidine, lysine, phenylalanine, tyrosine, valine, tryptophan, betaine, pyroglutamic acid, amino butyric acid, pyridine carboxylic acid, polyethylene glycol amino ether acetatic acid, or isoleucine.

Additional examples of the polishing accelerator may include a quinone compound such as 3-hydroxy-4-methyl-phenol anion, 3-hydroxy-4-hydroxymethyl-phenol anion, 4-methyl-benzene-1,3-diol, kojic acid, maltol propionate, and maltol isobutyrate.

Specific examples of the quinone compound may include 4-alkyl-benzene-1,3-diol, 3-hydroxy-4-alkyl-cyclohexa-2,5-dienone, 6-alkyl-3-oxo-cyclohexa-1,4-dienol anion, 3-hydroxy-6-alkyl-cyclohexa-2,4-dienone, 4-alkyl-3-oxo-cyclohexa-1,5-dienol anion, 3-hydroxy-4-alkyl-phenol anion, 5-hydroxy-2-alkyl-phenol anion, 3-hydroxy-4-alkyl-phenol anion, 5-hydroxy-2-hydroxyalkyl-phenol anion, 3-hydroxy-4-hydroxyalkyl-phenol anion, 3-hydroxy-4-hydroxyalkyl-cyclohexa-2,5-dienone, 6-hydroxyalkyl-3-oxo-cyclohexa-1,4-dienol anion, 3-hydroxy-6-hydroxyalkyl-cyclohexa-2,4-dienone, 4-hydroxyalkyl-3-oxo-cyclohexa-1,5-dienol anion, or 4-hydroxyalkyl-benzene-1,3-diol. Other additional examples of the polishing accelerator may include ammonium hydrogen phosphate, ammonium dihydrogen phosphate, bis(2-ethylhexyl)phosphate, 2-aminoethyl dihydrogen phosphate, 4-chlorobenzenediazonium hexafluorophosphate, nitrobenzenediazonium hexafluorophosphate, ammonium hexafluorophosphate, bis(2,4-dichlorophenyl) chlorophosphate, bis(2-ethylhexyl) hydrogenphosphate, bis(2-ethylhexyl)phosphite, calcium fluorophosphate, diethyl chlorophosphate, diethyl chlorothiophosphate, potassium hexafluorophosphate, pyrophosphoric acid, tetrabutylammonium hexafluorophosphate, or tetraethylammonium hexafluorophosphate.

### Oxidizing Agent

The oxidizing agent oxidizes a surface of a metal film to change the metal film into a state susceptible to oxidation. For the oxidizing agent, organic peroxides such as hydrogen peroxide, peracetic acid, perbenzoic acid, and tert-butylhydroperoxide; permanganate compounds such as potassium permanganate; dichromate compounds such as potassium dichromate; halogenic acid compounds such as potassium iodate; nitric acid compounds such as nitric acid and iron nitrate; perhalogenic acid compounds such as perchloric acid; persulfate such as sodium persulfate, potassium persulfate, and ammonium persulfate; percarbonates such as sodium percarbonate and potassium percarbonate; urea peroxide; heteropoly acids, and the like may be used. An auxiliary oxidizing agent such as iron nitrate hydrate, which can assist the oxidizing action of the oxidizing agent, may also be used together with the oxidizing agent.

### Dispersion Stabilizer

The slurry composition for chemical mechanical polishing may further include a dispersion stabilizer to ensure dispersion stability of the abrasive.

The dispersion stabilizer may include a nonionic polymer or a cationic organic compound. The dispersion stabilizer may include, for example, at least one selected from the group consisting of ethylene oxide, ethylene glycol, glycol distearate, glycol monostearate, glycol polymerate, glycol ethers, alcohols including alkylamines, a compound including polymerate ether, vinyl pyrrolidone, cellulose, and ethoxylate compounds. Specifically, the dispersion stabilizer may include at least one selected from the group consisting of diethylene glycol hexadecyl ether, decaethylene glycol hexadecyl ether, diethylene glycol octadecyl ether, eicosaethylene glycol octadecyl ether, diethylene glycol oleyl ether, decaethylene glycol oleyl ether, decaethylene glycol octadecyl ether, nonylphenol polyethylene glycol ether, ethylenediamine tetrakis(ethoxylate-block-propoxylate) tetrol, ethylenediamine tetrakis(propoxylate-block-ethoxylate) tetrol, polyethylene-blockpoly(ethylene glycol, polyoxyethylene isooctylphenyl ether, polyoxyethylene octylphenyl ether, polyoxyethylene tridecyl ether, polyoxyethylene sorbitan tetraoleate, polyoxyethylene sorbitol hexaoleate, polyethylene glycol sorbitan monolaurate, polyoxyethylene sorbitan monolaurate, sorbitan monopalmitate, FS-300 nonionic fluorosurfactant, FSN nonionic fluorosurfactant, FSO nonionic ethoxylated fluorosurfactant, vinyl pyrrolidone, 2,4,7,9-tetramethyl-5-decyne-4,7-diol ethoxylate, 8-methyl-1-nonanol propoxylate-block-ethoxylate, allyl alcohol 1,2-butoxylate-block-ethoxylate, polyoxyethylene branched nonylcyclohexyl ether, and polyoxyethylene isooctylcyclohexyl ether.

The dispersion stabilizer may be included in an amount of 0.1% by weight to 1% by weight with respect to the total amount of the slurry composition for chemical mechanical polishing.

### Surfactant

The surfactant may be selected and used from a nonionic-based surfactant, a cationic-based surfactant, an anionic-based surfactant, and an amphoteric surfactant.

The nonionic-based surfactant may include polyoxyethylene alkyl ethers such as polyoxyethylene lauryl ether and polyoxyethylene stearyl ether;

polyoxyethylene alkyl phenyl ethers such as polyoxyethylene octyl phenyl ether and polyoxyethylene nonierphenyl ether; sorbitan higher fatty acid esters such as sorbitan monolaurate, sorbitan monostearate, and sorbitan trioleate; polyoxyethylene sorbitan higher fatty acid esters such as polyoxyethylene sorbitan monolaurate; polyoxyethylene higher fatty acid esters such as polyoxyethylene monolaurate and polyoxyethylene monostearate; glycerin higher fatty acid esters such as oleic acid monoglyceride and stearic acid monoglyceride; polyoxyalkylenes such as polyoxyethylene, polyoxypropylene, and polyoxybutylene, and their block copolymers.

The cationic-based surfactant may include alkyl trimethyl ammonium chloride, dialkyl dimethyl ammonium chloride, benzalkonium chloride salt, or alkyl dimethyl ammonium ethosulfate.

The anionic-based surfactant may include carboxylic acid salts such as lauric acid sodium, oleic acid sodium, N-acyl-N-methylglycine sodium salts, and polyoxyethylene laurylether carboxylic acid sodium; sulfonates such as dodecylbenzene sulfonic acid sodium, dialkyl sulfosuccinate ester salts, and dimethyl-5-sulfoisophthalate sodium; ester sulfates such as sodium lauryl sulphate, sodium polyoxyethylene lauryl ether sulphate, and polyoxyethylene nonylphenyl ether sodium sulfate; or ester phosphates such as polyoxyethylene lauryl sodium phosphate and polyoxyethylene nonylphenyl ether sodium phosphate.

The amphoteric surfactant may include a carboxybetaine surfactant, an aminocarboxylic acid salt, imedazolinium betaine, lecithin, or alkylamineoxide.

The surfactant may be included in an amount of 0.001% by weight to 1.0% by weight, for example, 0.01% by weight to 0.5% by weight with respect to the total amount of the slurry composition for chemical mechanical polishing.

### Polishing Inhibitor

The polishing inhibitor may include a nitrogen-containing compound such as amines and low-molecular weight nitrogen-containing heterocyclic compounds. Specific examples may include benzotriazole, 1,2,3-triazole, or 1,2,4-triazole.

The polishing inhibitor may be included in an amount of 0.1% by weight to 1% by weight with respect to the total amount of the slurry composition for chemical mechanical polishing.

### Leveling Agent

The leveling agent can reduce irregularities of a surface to be polished, and may include, for example, ammonium chloride, ammonium lauryl sulfate, polyethylene glycol, triethanolamine polyoxyethylene alkyl ether sulfate, polyvinylpyrrolidone, or polyacrolein.

The leveling agent may be included in an amount of 0.01% by weight to 1.0% by weight, for example, 0.1% by weight to 1.0% by weight with respect to the total amount of the slurry composition for chemical mechanical polishing.

### Corrosion Inhibitor

The corrosion inhibitor can protect a surface to be polished from corrosion, and can prevent recess, erosion, or irregularities from occurring on the polished surface.

The corrosion inhibitor may include triazole and derivatives thereof, benzene triazole and derivatives thereof, or a combination thereof. The triazole derivatives may include, for example, an amino-substituted triazole compound, or a bi-amino-substituted triazole compound, but is not limited thereto.

The corrosion inhibitor may be included in an amount of 0.001% by weight to 1.0% by weight, for example, 0.01% by weight to 0.5% by weight with respect to the total amount of the slurry composition for chemical mechanical polishing.

### Amine Compound

The amine compound may be a compound having 1 to 20 carbon atoms and having two or more amine groups in one molecule. The amine compound may include, for example, diamines, triamines, tetramines, pentamines, hexamines, heptamines, and the like. Specific examples of the amine compound may be one or more selected from the group consisting of, but are not limited to, spermine, methane diamine, ethane-1,2-diamine, propane-1,3-diamine, butane-1,4-diamine, pentane-1,5-diamine, hexane-1,6-diamine, heptane-1,7-diamine, octane-1,8-diamine, diethylene triamine, dipropylene triamine, triethylenetetramine (TETA), tripropylene tetramine, tetraethylene pentamine (TEPA), pentaethylenehexamine (PEHA), hexaethylene heptamine, bis(hexamethylene)triamine, N-(3-aminopropyl)ethylenediamine, N,N′-bis(3-aminopropyl)ethylenediamine, N,N′-bis(2-aminoethyl)-1,3-propanediamine, N,N,N′-tris(3-aminopropyl)ethylenediamine, N-3-aminopropyl-1,3-diaminopropane, N,N′-bis(3-aminopropyl)-1,3-diaminopropane, N,N,N′-tris(3-aminopropyl)-1,3-diaminopropane, bis-(3-aminopropyl)amine, N,N,N′N′-tetrakis(2-hydroxylpropyl)ethylenediamine, N,N,N′,N′-tetramethyl propanediamine, di-t-butylethylenediamine, 3,3′-iminobis(propylamine), N-methyl-3,3′-iminobis(propylamine), N,N′-bis(3-aminopropyl)-1,3-propylenediamine, N,N′-bis(3-aminopropyl)-1,4-butylenediamine, N,N′-bis(4-aminobutyl)-1,4-butanediamine, N,N′-bis(2-aminoethyl)-1,4-butanediamine, N,N′-bis(2-aminoethyl)ethylenediamine, bis(3-aminopropyl)amine, bis(4-aminobutyl)amine, bis(5-aminopentyl)amine, N-(6-aminohexyl)-1,6-hexanediamine, hexahydro-1,3,5-triazine, N-methylethylenediamine, N-ethylethylenediamine, N-propylethylenediamine, N-butylethylenediamine, N-methyl-1,3-diaminopropane, N-methyl-1,4-diaminobutane, N-methyl-1,5-diaminopentane,N-methyl-1,6-diaminohexane, N-methyl-1,7-diaminoheptane,N-methyl-1,8-diaminoctane, N-methyl-1,9-diaminononane, N-methyl-1,10-diaminodecane,N-methyl-1,11-diaminoundecane, N-methyl-1,12-diaminododecane, 1,3-bis(aminomethyl)cyclohexane, 1,4-bis(aminomethyl)cyclohexane, piperazine, and derivatives thereof.

The amine compound may be included in an amount of 0.001% by weight to 1% by weight, for example, 0.005% by weight to 0.5% by weight with respect to the total amount of the slurry composition for chemical mechanical polishing.

### Carrier

The carrier may be any liquid capable of substantially uniformly dispersing the organic particles or a polishing booster, and for example, may be an aqueous solvent or an organic solvent.

The carrier may include, for example, water, deionized water, ultrapure water, alcohol (e.g., propenyl alcohol, isopropyl alcohol, ethanol, 1-propanol, methanol, 1-hexanol, and the like), aldehyde (e.g., formaldehyde, acetaldehyde, and the like), ester (e.g., ethyl formate, propyl formate, ethyl acetate, methyl acetate, methyl lactate, butyl lactate, ethyl lactate, and the like), ketone (e.g., acetone, diacetone alcohol, methyl ethyl ketone, and the like), dimethyl sulfoxide, tetrahydrofuran, dioxane, diglyme, amide (e.g., N,N-dimethyl formamide, dimethyl imidazolidinone, N-methyl pyrrolidone, and the like), polyhydric alcohol and derivatives thereof (e.g., ethylene glycol, glycerol, diethylene glycol, diethylene glycol monomethyl ether, and the like), a nitrogen-containing organic compound (e.g., acetonitrile, amylamine, isopropylamine, imidazole, dimethyl amine, and the like), or a mixture thereof.

After formation of the slurry composition, the carrier may be included in a residual amount with respect to the total amount of the slurry composition for chemical mechanical polishing. For example, the carrier may be removed from the slurry composition after the formation of the slurry composition, but a small amount of the carrier may remain in the slurry composition as a residue.

The slurry composition for chemical mechanical polishing according to an embodiment may be manufactured by mixing the above-described abrasive and the photoinitiator, and optionally, one or more of the above-described additives.

Below, each member of the chemical mechanical polishing apparatus 100 will be described.

Referring to FIG. 1, the head unit 110 may be a rotatable member on which a wafer WF can be mounted. Specifically, the head unit 110 can rotate in a certain direction. The head unit 110 may be pressed in a direction of the polishing pad 140 so that the wafer WF is polished.

The wafer WF may be, as a non-limiting example, a semiconductor wafer made of silicon as a base material and having a circular shape. As a non-limiting example, the wafer WF may consist of a member made of a material other than silicon, such as gallium arsenide, sapphire, gallium nitride, ceramics, resin, and silicon carbide.

The slurry supplier 120 may be a member that supplies the above-described slurry composition to the polishing pad 140. The slurry supplier 120 is located above the polishing pad 140, and supplies the slurry composition to the polishing pad 140. The slurry composition is transferred to the wafer WF through micropores formed in the polishing pad 140, so that mechanical polishing by rotation of the head unit 110 and chemical polishing by the slurry composition can be performed simultaneously.

Specifically, the slurry supplier 120 may include an injection port and a pipe for delivering the slurry composition. The injection port may be adjacent to the polishing pad 140. Accordingly, the slurry composition can be supplied onto the polishing pad 140 through the pipe and injection port.

The polishing platen 130 is located below the polishing pad 140, and may be a member that applies rotational energy so that the polishing pad 140 can rotate in a certain direction.

The polishing platen 130 includes a light irradiation member 160. The light irradiation member 160 is located in the polishing platen 130 so that light can be irradiated to a lower part of the wafer.

The light irradiation member 160 performs irradiation of light so as to carry out a photo reaction with the slurry composition supplied from the slurry supplier 120, in which the abrasive 10 in which the surface of the polishing particle 11 is coated with a photoreactive monomer or oligomer and the photoinitiator 20 are mixed.

Referring to FIG. 4, when light is irradiated to the lower part of the wafer through the light irradiation member 160, agglomeration among the abrasives 10 occurs more actively in a pattern region of the lower part of the wafer, i.e., a high-step region, in which the formation of agglomerates 30 can be concentrated. On the other hand, an amount of light reaching an upper region of the wafer is relatively less than that of the pattern region of the lower part, so in the upper region, more abrasives 10 which are not agglomerated are present compared to the lower region. With this, the ability to remove steps in the high-step region of the wafer can be enhanced by the agglomerates 30 formed by polymerization.

The light irradiation member 160 may include a light source such as a light emitting diode (LED) for irradiation of light. For example, the light source may be composed of at least one unit. The unit may be a pixel that emits light in the light irradiation member 160.

The light irradiated from the light irradiation member 160 may include at least one of visible light, ultraviolet light, and infrared light. The light may be, for example, visible light or ultraviolet light.

The polishing pad 140 is located on the polishing platen 130, and may be rotatable while being supported by the polishing platen 130. The polishing pad 140 uniformly planarizes the surface of the wafer WF, and may be a member that performs mechanical polishing.

The polishing pad 140 may include or may be formed of polyurethane, for example.

The polishing pad 140 may be transparent to allow light irradiated toward the wafer from the above-described light irradiation member 160 to pass therethrough. A region of at least a part of the polishing pad 140 through which light passes may be transparent.

The conditioner 150 may be adjacent to the polishing pad 140. The conditioner 150 may perform a conditioning process on the polishing pad 140. Accordingly, the conditioner 150 can stably maintain a state of the polishing surface of the polishing pad 140 so that the wafer WF is effectively polished during the chemical mechanical polishing process.

Specifically, the conditioner 150 can maintain a surface roughness of the polishing pad 140 in an optimal state by polishing the surface of the polishing pad 140. More specifically, the conditioner 150 finely cuts the surface of the polishing pad 140 to prevent numerous foam micropores, which serve to contain the slurry mixed with the abrasive and chemicals on the surface of the polishing pad 140, from being clogged, thereby allowing the slurry filled in the foam micropores of the polishing pad 140 to be smoothly supplied to the wafer WF.

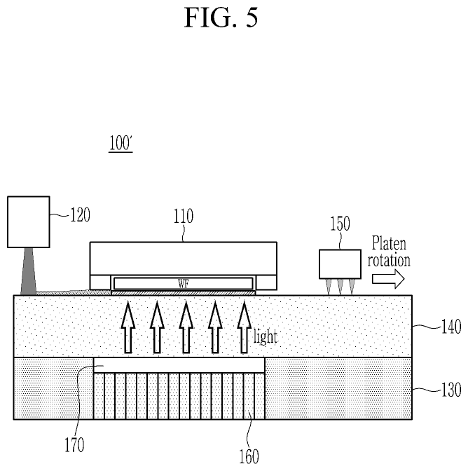

FIG. 5 is a cross-sectional view of a chemical mechanical polishing apparatus according to another embodiment.

Referring to FIG. 5, a chemical mechanical polishing apparatus 100′ according to an embodiment includes a head unit 110 on which the wafer WF can be mounted, a slurry supplier 120 that supplies the above-described slurry composition to a polishing pad 140, a polishing platen 130, the polishing pad 140 located on the polishing platen 130, and a conditioner 150. The polishing platen 130 includes a light irradiation member 160 for irradiation of light in order to perform a light reaction with the slurry composition supplied from the slurry supplier 120. The detailed descriptions of the head unit 110, the slurry supplier 120, the polishing pad 140, and the conditioner 150 are the same to the extent that they do not contradict that shown in FIG. 1.

According to an embodiment, the polishing platen 130 may further include a protection member 170 located on the light irradiation member 160.

The protection member 170 may be a member for protecting the light irradiation member 160 arranged in the polishing platen 130, and may also be a member capable of improving adhesion between the light irradiation member 160 and the polishing pad 140. The protection member 170 may be transparent. In an embodiment, the entirety of the protection member 170 may be transparent. In an embodiment, the protection member 170 may include or may be a transparent glass or a transparent plastic.

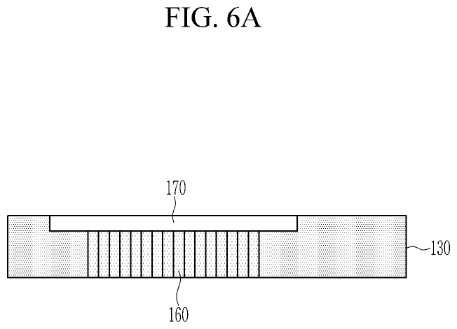

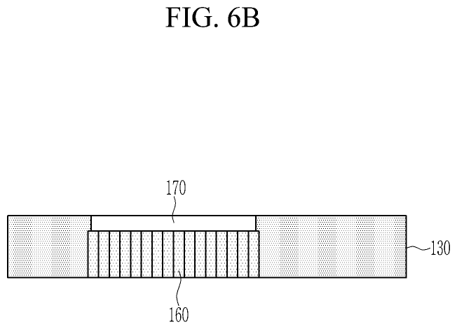

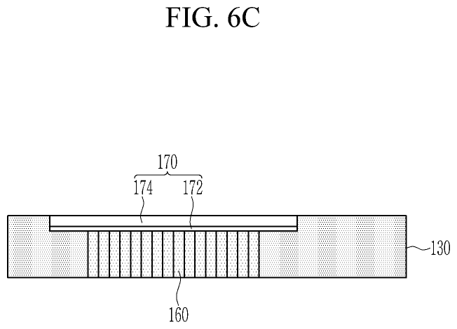

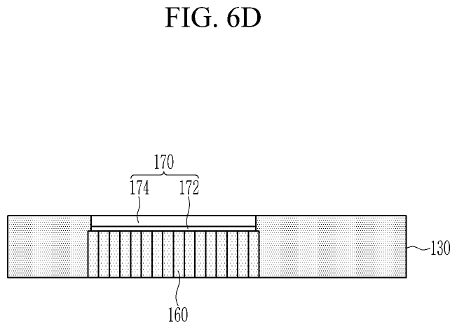

A specific example of the protection member 170 will be described with reference to FIG. 6A to FIG. 6D.

FIG. 6A to FIG. 6D are cross-sectional views of the polishing platen showing examples of the polishing platen in the chemical mechanical polishing apparatus of FIG. 5.

Referring to FIG. 6A and FIG. 6B, the polishing platen 130 may include the protection member 170 located on the light irradiation member 160. The protection member 170 may be transparent. In an embodiment, the entirety of the protection member 170 may be transparent. In an embodiment, the protection member 170 may include a transparent plastic such as a cross-linked polydimethylsiloxane, etc., Referring to FIG. 6C and FIG. 6D, the polishing platen 130 may include the protection member 170 located on the light irradiation member 160, and the protection member 170 may include a first protection member 172 located on the light irradiation member 160 and a second protection member 174 located on the first protection member 172. The first protection member 172 may be transparent. In an embodiment, the first protection member 172 may include a transparent plastic such as a cross-linked polydimethylsiloxane, etc., The second protection member 174 may be transparent. In an embodiment, the second protection member 174 may include a transparent glass such as a quartz, etc.,

In an embodiment, the protection member 170 may have the same width in the horizontal direction as the light irradiation member 160. In an embodiment, the protection member 170 may have a larger width in the horizontal direction than the light irradiation member 160, as shown in FIG. 6A and FIG. 6C. In an embodiment, the protection member 170 may have a smaller width in the horizontal direction than the light irradiation member 160, as shown in FIG. 6B and FIG. 6D.

The following Examples illustrate the above-described embodiments in more detail. However, the following Examples are for illustrative purposes only and do not limit the scope of the invention.

### Example 1

An abrasive with polyethylene glycol diacrylate (PEGDA) coated on a surface of silica (PL-1, FUSO CHEMICAL) having a primary particle size of 15 nm, and 2,2′-azobis [2-methyl-N-(2-hydroxyethyl) propionamide] as a photoinitiator were prepared. The abrasive was prepared by adding PEGDA during the synthesis of silica using a sol-gel method, and in this case, silica and PEGDA were used at a weight ratio of 10:1.

Then, 1% by weight of the abrasive, 0.5% by weight of the photoinitiator, 0.06% by weight of benzotriazole, 0.4% by weight of ammonium dihydrogen phosphate, 0.5% by weight of triammonium citrate, 1.6% by weight of hydrogen peroxide, and the remaining amount of water were mixed to prepare a slurry composition.

### Example 2

An abrasive with 3,4-epoxycyclohexylmethyl-3,4-epoxycyclohexanecarboxylate (EPOX) coated on the surface of silica (PL-1, FUSO CHEMICAL) having a primary particle size of 15 nm, and diphenyl iodonium trifluoromethane sulfonate as a photoinitiator were prepared. The abrasive was prepared by adding EPOX during the synthesis of silica using a sol-gel method, and in this case, silica and EPOX were used at a weight ratio of 10:1.

Then, 1% by weight of the abrasive, 0.5% by weight of the photoinitiator, 0.06% by weight of benzotriazole, 0.4% by weight of ammonium dihydrogen phosphate, 0.5% by weight of triammonium citrate, 1.6% by weight of hydrogen peroxide, and the remaining amount of water were mixed to prepare a slurry composition.

### Comparative Example 1

1% by weight of silica (PL-1, FUSO CHEMICAL) having a primary particle size of 15 nm, 0.06% by weight of benzotriazole, 0.4% by weight of ammonium dihydrogen phosphate, 0.5% by weight of triammonium citrate, 1.6% by weight of hydrogen peroxide and the remaining amount of water were mixed to prepare a slurry composition.

### Polishing Performance Evaluation

The polishing performance was confirmed when a patterned wafer was polished using the slurry compositions according to Examples 1 and 2 and Comparative Example 1. The polishing performance was measured under following conditions, and the results are shown in Table 1 below.

An Ma-200e polishing machine (Musashino Denshi Co., Ltd.) was used for polishing, and polishing was performed under conditions of a rotational speed of 90 revolutions per minute (RPM) and a polishing pressure of 24 kPa by using an IC1010 polishing pad (Dow Chemical Co., Ltd.).

TABLE 1

| | Polishing |
|---|---|
| | speed |
| | (nm/min) |
| Example 1 | 170 |
| Example 2 | 160 |
| Comparative | 89 |
| Example 1 | |

From Table 1, it can be seen that the polishing performance of Examples 1 and 2 using the slurry composition for chemical mechanical polishing according to an embodiment is superior to that of Comparative Example 1.

Although the embodiments have been described in detail, the scope of the present invention is not limited thereto, and various modifications and improvements made by one skilled in the art by using the basic concept of the present invention defined in the following claims also fall within in the scope of the present invention.

What is claimed is:

1. A slurry composition for chemical mechanical polishing comprising:
an abrasive comprising a polishing particle and a coating layer surrounding the polishing particle; and
a photoinitiator,
wherein the polishing particle comprises a metal oxide, and
wherein the coating layer comprises a photoreactive monomer or oligomer.

2. The slurry composition of claim 1,
wherein the metal oxide comprises SiO₂, Al₂O₃, CeO₂, ZrO₂, TiO₂, MnO₂, Mn₂O₃, or a mixture thereof.

3. The slurry composition of claim 1,
wherein the photoreactive monomer or oligomer comprises a radically polymerizable compound, a cationically polymerizable compound, or a mixture thereof.

4. The slurry composition of claim 3,
wherein the radically polymerizable compound comprises a (meth) acrylate-based compound, a thiol-based compound, an alkene-based compound, an alkyne-based compound, or a mixture thereof.

5. The slurry composition of claim 3,
wherein the radically polymerizable compound is one or more selected from the group consisting of a (meth) acrylate-based compound comprising polyethyleneglycol diacylate (PEGDA), urethane dimethacrylate (UDMA), triethylenglycol dimethacrylate (TEGDMA), bisphenol A glycidyl methacrylate (Bis-GMA), trimethylolpropane triacrylate (TTA), bisphenol A ethoxylate diacrylate (Bis-EDA) or a mixture thereof; a thiol-based compound comprising trimethylolpropane tris(3-mercaptopropionate) (TMPMP), pentaerythritol tetra(3-mercaptopropionate) (PETMP), tris [2-(3-mercaptopropionyloxy)ethyl] isocyanurate (TMI), pentaerythritol tetrakis(3-mercaptopropionate) (PE-1) or a mixture thereof; an alkene-based compound comprising triallyl-1,3,5-triazine-2,4,6 (1H,3H,5H)-trione (TTT); and an alkyne-based compound comprising 1,4-butandiol dipent-4-yn-2-yl carbonate (4MPC), 2,2-bis [4-(2-hydroxy) ethoxyphenyl] propane dibut-3-yn-1-yl carbonate (BABC), tricyclo[5.2.1.0 (2,6)] decane-4,8-dimethanol dibut-3-yn-1-yl carbonate (TCBC) and a mixture thereof.

6. The slurry composition of claim 3,
wherein the cationically polymerizable compound comprises an epoxy-based compound, a vinyl ether-based compound, an oxetane-based compound, or a mixture thereof.

7. The slurry composition of claim 3,
wherein the cationically polymerizable compound includes an epoxy-based compound comprising 3,4-epoxycyclohexylmethyl-3,4-epoxycyclohexanecarboxylate (EPOX), bisphenol A diglycidylether (DGEBA) or a mixture thereof; a vinyl ether-based compound comprising 1,4-cyclohexane dimethanol divinylether (CDVE); and an oxetane-based compound comprising disubstituted oxetane (DSO).

8. The slurry composition of claim 1,
wherein the photoinitiator comprises a radical initiator, a cationic initiator, or a mixture thereof.

9. The slurry composition of claim 8,
wherein the radical initiator comprises an azo compound, a peroxide compound, a halogen compound, or a mixture thereof.

10. The slurry composition of claim 8,
wherein the cationic initiator comprises a diazosulfone compound, a sulfonium salt, an iodonium salt, a sulfonate compound, or a mixture thereof.

11. The slurry composition of claim 1,
wherein the abrasive is included in an amount selected from a range of 0.01% by weight to 10% by weight with respect to a total amount of the slurry composition for chemical mechanical polishing.

12. The slurry composition of claim 1,
wherein the photoinitiator is included in an amount selected from a range of 0.01% by weight to 10% by weight with respect to a total amount of the slurry composition for chemical mechanical polishing.

13. The slurry composition of claim 1,
wherein when the photoreactive monomer or oligomer is a radically polymerizable compound, the photoinitiator is a radical initiator, or
wherein when the photoreactive monomer or oligomer is a cationically polymerizable compound, the photoinitiator is a cationic initiator.

14. The slurry composition of claim 1,
wherein when irradiated with light, the photoreactive monomer or oligomer of the abrasive is polymerized by the photoinitiator to form agglomerate of the abrasive and other abrasives.

15. A chemical mechanical polishing apparatus comprising:
a polishing platen comprising a light irradiation member;
a polishing pad located on the polishing platen; and
a slurry supplier configured to supply a slurry composition for chemical mechanical polishing,
wherein the slurry composition includes a polishing particles coated with a photoreactive monomer or oligomer and a photoinitiator.

16. The chemical mechanical polishing apparatus of claim 15,
wherein the polishing pad is transparent.

17. The chemical mechanical polishing apparatus of claim 15,
wherein the polishing platen further comprises a protection member located on the light irradiation member.

18. The chemical mechanical polishing apparatus of claim 17,
wherein the protection member is transparent.

19. A chemical mechanical polishing apparatus comprising:
a polishing platen comprising a light irradiation member;
a transparent polishing pad located on the polishing platen; and
a slurry supplier configured to supply a slurry composition for chemical mechanical polishing,
wherein the slurry composition includes a polishing particles coated with a photoreactive monomer or oligomer and a photoinitiator.

20. The chemical mechanical polishing apparatus of claim 19,
wherein the polishing platen further comprises a protection member located on the light irradiation member.
